(19) United States
(12) Patent Application Publication
(10) Pub. No.: US 2010/0156437 A1
(43) Pub. Date: Jun. 24, 2010

(54) Apparatus and Methods of Demonstrating Cabling Performance in Real Time

(76) Inventors: Terry Cobb, Plano, TX (US); Peter B. Kidd, Murphy, TX (US); Richard Y. Mei, Parker, TX (US); Yinglin (Frank) Yang, Plano, TX (US)

Correspondence Address: Timothy J. Wall;Myers Bigel Sibley & Sajovec, P.A., P. O. Box 37428, Raleigh, NC, 27627, US

(21) Appl. No.: 12/644,417

(22) Filed: Dec. 22, 2009

Related U.S. Application Data
(60) Provisional application No. 61/139,910, filed on Dec. 22, 2008.

(51) Int. Cl. G01R 29/26

(52) U.S. Cl. 324/614

(57) ABSTRACT

Provided are apparatus and methods for demonstrating cable performance in real time. An apparatus may include a cable bundle of multiple disturber cables and a test cable arranged proximate one another, each coupled between a pair of data transceivers. A data loading device is configured to generate data for transmission across at least one of the disturber cables and the test cable, and a transmission data analyzer is configured to analyze data transmission performance of the test cable.

### RELATED APPLICATION

This application claims priority from U.S. Provisional Patent Application No. 61/139,910, filed on Dec. 22, 2008, the disclosure of which is incorporated herein by reference as if set forth fully herein.

### FIELD OF THE INVENTION

The present invention relates generally to testing and, more particularly, to apparatus, systems and methods for demonstrating test data.

### BACKGROUND

In order to evaluate different cabling configurations for high speed data cables, present methods may use a network analyzer to measure various performance parameters (i.e.: alien crosstalk, insertion loss, etc.). The parameters may then be mathematically combined together to represent a signal to noise impairment. A disadvantage of this method may be that the measurement of the parameters may be a lengthy process and the manner in which the impairments are mathematically combined may not reflect what actually happens.

Additionally, such methods may provide difficulties in testing different cabling configurations and/or small cabling configuration changes. For example, some prior art demonstrations test three cabling configurations in real time using a digital video signal. The video signal source and receiver may be switched between the three cabling configurations using patch cords. The video corresponding to a first cable may be displayed on a screen and any bit errors may show up as white specs in the video. The bit errors may result from interference/noise that is coupled onto the first cable from two other cables, that also each carry a digital video signal, that are bundled to the first cable. By watching the demonstration, an observer may see the difference in the cabling configurations by the frequency that errors (represented as white specs) appear on the display.

### SUMMARY

Pursuant to some embodiments of the present invention, apparatus and methods for demonstrating cabling performance in real time are provided. In some embodiments, an apparatus may include a cable bundle of multiple disturber cables and a test cable arranged proximate one another and multiple data transceivers that are connected in pairs across the test cable and across at least one of the disturber cables. An apparatus may include a data generator that is configured to generate data for transmission across at least one of the disturber cables and the test cable and a transmission data analyzer that is configured to analyze data transmission performance of the test cable.

In some embodiments, data transmission performance includes a real-time signal-to-noise ratio (“SNR”). Some embodiments provide that the transmission data analyzer determines the real time SNR on the test cable. In some embodiments, the transmission data analyzer determines the real time SNR on each of multiple differential conductor pairs included within the test cable.

Some embodiments include a visual output device that is configured to display the real-time SNR as an average SNR and a worst value SNR.

In some embodiments, the data for transmission across the disturber cables includes a combination of noise sources and the SNR includes a ratio of a received signal on the test cable divided by the combination of noise sources. Some embodiments provide that the data for transmission across the disturber cables is selectively stopped while the transmission data analyzer is analyzing the data transmission performance of the test cable to observe a change in the SNR and to determine a sensitivity to crosstalk corresponding to ones of the disturber cables.

Some embodiments include a first cable bundle and a second cable bundle such that the first cable bundle includes a first test cable of a first type and the second cable bundle includes a second test cable of a second type that is different from the first type. The transmission data analyzer may be configured to analyze data transmission performance of the first test cable and the second test cable to provide comparative data transmission performance between the first and second test cables.

In some embodiments, the data generated for transmission across the disturber cables includes randomly generated signals.

Methods according to some embodiments of the present invention may include arranging multiple disturber cables that are configured to generate externally originating noise proximate a test cable that is configured to be analyzed for performance and terminating each end of at least one of the disturber cables and the test cable between multiple data transceivers, wherein each cable is terminated between two of the data transceivers. Methods according to some embodiments may include transmitting random signals via the at least one of the disturber cables, transmitting data via the test cable, and analyzing the performance of the test cable.

Some embodiments provide that analyzing the performance of the test cable includes determining a real-time signal-to-noise ratio (“SNR”). In some embodiments, determining the real-time SNR includes determining the real-time SNR on the test cable and/or determining the real-time SNR on each of multiple of differential conductor pairs included within the test cable. In some embodiments, determining the real-time SNR on the test cable includes determining an average SNR and a worst value of SNR on the test cable.

Some embodiments include displaying the SNR using a visual output device and storing the SNR on a computer readable medium.

In some embodiments, transmitting random signals via at least one of the disturber cables includes selectively stopping transmitting random signals while analyzing the performance of the test cable and determining a change in the performance of the test cable to determine a sensitivity to crosstalk corresponding to the disturber cable(s).

In some embodiments, the random signals transmitted across a disturber cable may include a combination of noise sources and the SNR includes a ratio of a received signal on the test cable divided by the combination of noise sources.

Some embodiments of the present invention include methods for demonstrating cable performance that include arranging first disturber cables and second disturber cables that are configured to generate externally originating noise proximate respective first and second test cables that are each configured to be analyzed for performance. Embodiments may include terminating each end of at least one of the first disturber cables and the second disturber cables and the first and second test cables between respective ones of multiple data transceivers, wherein each cable is terminated between two of the plurality of data transceivers. Random signals are transmitted via the first disturber cables and the second disturber cables. Data is transmitted via the first test cable and via the second test cable. The performances of the first test cable and the second test cable are analyzed and compared.

In some embodiments, analyzing the performance of the first test cable and the second test cable includes determining a real-time signal-to-noise ratio (“SNR”) for each of the first and second test cables. Some embodiments provide that analyzing the performance of the first test cable and the second test cable includes determining the real-time SNR on each of multiple differential conductor pairs included within the each of the first test cable and the second test cable.

### BRIEF DESCRIPTION OF THE DRAWINGS

FIG. 1 is a block diagram illustrating a system for demonstrating cabling performance in real time according to some embodiments of the present invention.

FIG. 2 is a cross-sectional cut-away view of a cable bundle for demonstrating cabling performance in real time according to some embodiments of the present invention.

FIG. 3 is a block diagram illustrating a method for demonstrating cabling performance in real time according to some embodiments of the present invention.

FIG. 4 is a block diagram illustrating an apparatus for demonstrating cabling performance in real time according to some embodiments of the present invention.

FIG. 5 is a block diagram illustrating a method for demonstrating cabling performance in real time according to some embodiments of the present invention.

### DETAILED DESCRIPTION

The present invention now is described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that when an element is referred to as being “coupled” to another element, it can be coupled directly to the other element, or intervening elements may also be present. In contrast, when an element is referred to as being “directly coupled” to another element, there are no intervening elements present. Likewise, it will be understood that when an element is referred to as being “connected” or “attached” to another element, it can be directly connected or attached to the other element or intervening elements may also be present. In contrast, when an element is referred to as being “directly connected” or “directly attached” to another element, there are no intervening elements present. The terms “upwardly”, “downwardly”, “front”, “rear” and the like are used herein for the purpose of explanation only.

Unless otherwise defined, all technical and scientific terms used herein have the same meaning as commonly understood by one of ordinary skill in the art to which this invention belongs. The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. As used herein, the term “and/or” includes any and all combinations of one or more of the associated listed items.

Pursuant to embodiments of the present invention, apparatus and methods are provided for comparing cabling configurations using actual data interfaces connected to the cables under test. Some embodiments include a new demonstration, also referred to as a cabling demonstration, for comparing cabling configurations using actual 10 GBASE-T interfaces connected to the cabling under test. In this manner, the demonstration may be done in real time and represent what may actually happen. Some embodiments of a cabling configuration to be demonstrated may include a “victim” and/or “test” cable that will be illustrated and described below. The test cable may be surrounded by other cables that may be referred to as disturbers that may also be running 10 GBASE-T. Each of the cables includes connectors that may be terminated to allow connections to be switched to provide different cabling configurations.

Differences between the cabling configurations may be demonstrated using a control computer. The control computer may be used to interface with the test 10 GBASE-T interface at each end of the test cable. The control computer may include a management interface to communicate with the 10 GBASE-T interface. In some embodiments, the control computer may set each 10 GBASE-T interface into a Bit Error Rate (“BER”) test mode. In this mode, scrambled data may be sent between the two 10 GBase-T interfaces and checked for bit errors.

The disturber cables may be connected to 10 GBASE-T interfaces at each end. The connected disturber 10 GBASE-T interfaces may start sending scrambled data between each other. In this manner, the cabling demonstration may illustrate the effects of external impairments such as, for example, alien crosstalk from the disturber cables on the test cable. Further, the cabling demonstration may illustrate the internal impairments in the test cable as incurred through use and/or operation thereof. In this manner, the cabling demonstration may provide an example of how the cabling configuration would perform in an installation.

It will be appreciated that in 10 GBASE-T cabling systems, each cable typically includes a total of eight conductors or wires that are arranged as four differential pairs of conductors. Each differential pair may carry a differential information signal so that each cable may carry up to four information signals at a time. In some embodiments, a 10 GBASE-T interface may allow the control computer to read the Signal-to-Noise (“SNR”) on each cable pair coupled to the interface. The control computer may continually read the SNR on each cable pair and calculate an average SNR across the cable pairs. The average SNR and the worst SNR on a pair may be displayed on a monitor or other type of visual output device, stored in a data storage device, and/or printed. For example, the worst SNR may include the lowest value of the SNR. In some embodiments, the control computer may check for the receipt of bit errors. Bit errors may also be output to a visual output device and may be quantified, for example, as a bit error rate (BER), which may be determined as the total bit errors divided by the total bits received. The SNR and BER may be displayed continuously for both 10 GBASE-T interfaces attached to the test cable.

In some embodiments, the SNR may be determined as the ratio of the received signal on the test cable divided by the true combination of all noise sources or impairments at each end of the cabling configuration. In this manner, real time actual performance of the cabling configuration may be provided. The SNR may also be related to the BER. For example, as the SNR goes down the BER may go up. An advantage of considering the SNR is that it can show small performance differences much better than BER information. In some embodiments, the cabling demonstration may facilitate the addition and/or removal of any disturbing cable during the test. In this manner, the increase or decease in the SNR may be illustrated in real time. By illustrating the increase or decrease of the SNR in real time, the sensitivity of the cabling configuration to alien crosstalk from disturbing cables may be illustrated and/or demonstrated.

In some embodiments, the difference in cabling configurations may be demonstrated by stopping the test on the present cabling configuration. When the test is stopped, the control computer may freeze the SNR and/or BER on the screen. In this manner, the operator may change to a new cabling configuration and start a new test. When the new test starts, the control computer may open a new window for the new cabling configuration to allow a comparison to the results of the previous configuration. In this manner, a real time illustration may be provided corresponding to the performance of different cabling configurations in a cabling installation. Real time illustrations described herein are in contrast with prior art demonstrations that are not true representations of what would happen in a system that is running high speed data and may only show observable bit errors or gross changes.

In some embodiments, a cabling demonstrator may include a six-around-one demonstration system that uses UTP cabling channels in a worst-case, full-reach, 4-connector channel configuration. The cabling demonstration is designed to show the raw bandwidth and payload throughput capability of the 10 GBASE-T link in a real world scenario. In some embodiments, the test configurations may be used to illustrate performance between two PCs.

While in certain embodiments of the present invention the test and disturber cables carry one or more differential pairs, it will be appreciated that embodiments of the present invention are not limited to such configurations. Instead, embodiments of the present invention encompass both systems in which each cable carries a single information signal on a single conductor and systems in which each cable carries one or more information signals on one or more differential pairs of conductors, as well as combinations thereof. It will also be appreciated that with disturber cables that include multiple information signal carrying paths (e.g., multiple differential wire pairs), one or more than one of these multiple paths may carry a data signal during the test/demonstration. Likewise, some or all of the information signal paths on the test cable may carry test data during a test or demonstration, and performance parameters for some or all of these paths may be determined and/or displayed. Although presented in the context of a 10 GBase-T data format, which may include a 10 Gbit/s data transmission rate over unshielded twisted pair (UTP) cable, the apparatus and methods herein may be used in conjunction with a variety of data transmission protocols, formats, cabling media and/or standards.

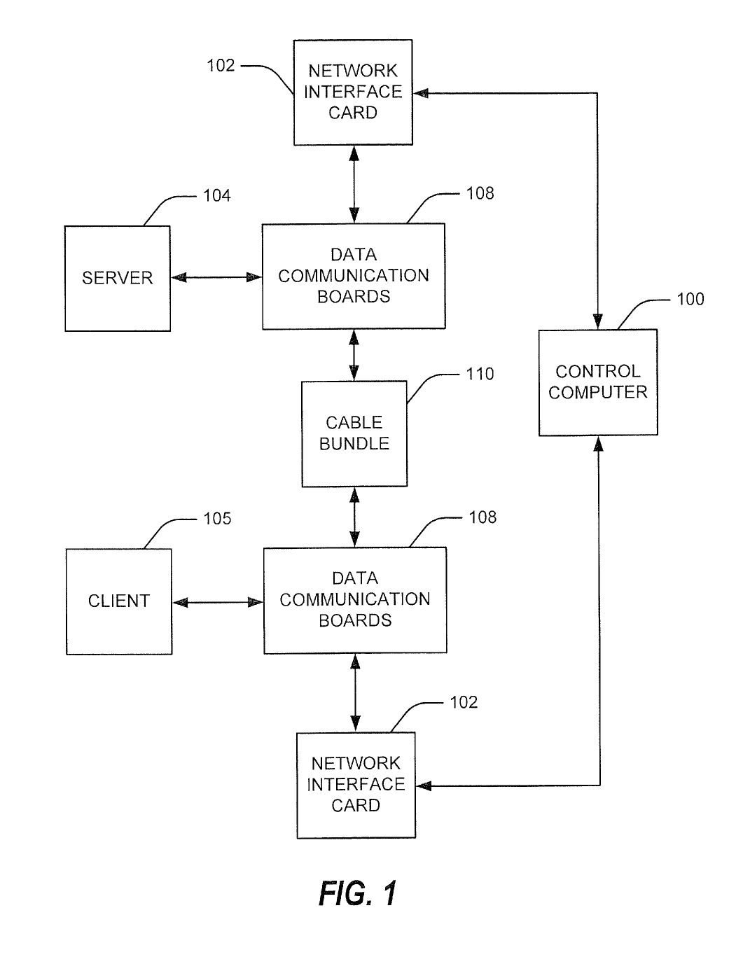

Reference is now made to FIG. 1, which is a block diagram of a system for demonstrating cabling performance in real time according to some embodiments of the present invention. A cable bundle 110 is connected between multiple data communication boards 108. The cable bundle 110 may include a test cable that is proximate one or more disturber cables. The test cable may include, for example, eight insulated conductive wires that are configured as four different pairs of wires that may be used to carry four information signals. In some embodiments, the test cable may be surrounded by six disturber cables. Each disturber cable may likewise include, for example, eight insulated conductive wires that are configured as four different pairs of wires that may be used to carry four information signals. The data communication boards 108 at the ends of the cable bundle 110 may be connected, respectively, to a server 104 and a client 105. The server 104 and client 105 may be configured to generate data for transmission across the test cable and one or more of the disturber cables. In some embodiments, the data transmitted via the disturber cables may be randomly generated data that may create the same crosstalk characteristics as an actual information signal. The data transmitted via the test cable may include predetermined content. Some embodiments provide that data transmitted via the disturber cables may include predetermined data content and/or format having known and/or predictable crosstalk characteristics.

Each of the data communication boards 108 may be connected to a control computer 100 via, for example, a network interface card 102. The control computer 100 can receive performance data from the data communication board(s) 108 regarding the test cable, for example, for analysis, storage and/or display. In some embodiments, the cable bundle 110 is sufficiently long so as to duplicate the cable performance as if the cable bundle 110 were installed. For example, some embodiments provide for a 100 meter cable bundle. In some embodiments, the test and/or disturber cables include UTP cable.

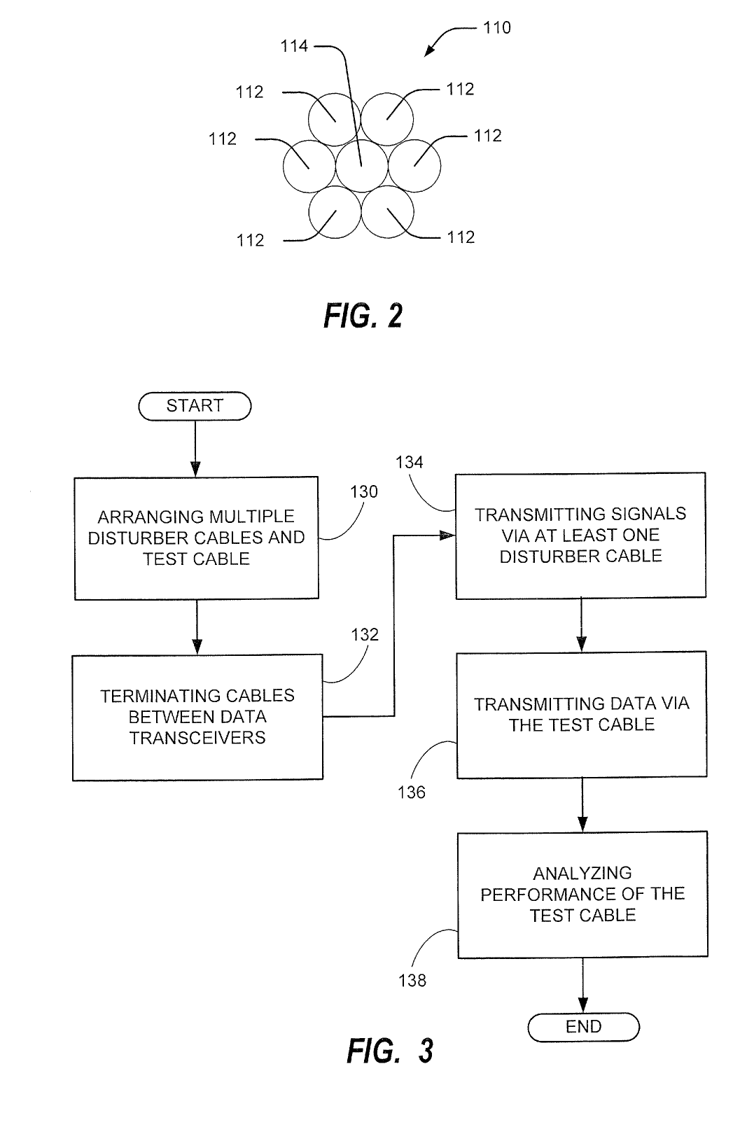

Reference is now made to FIG. 2, which is a cross-sectional view of a cable bundle for demonstrating cabling performance in real time according to some embodiments of the present invention. The cable bundle 110 may include a test cable 114 and multiple disturber cables 112. For example, as illustrated, the test cable 114 may be surrounded by six disturber cables 112. Some embodiments provide for different combinations and/or quantities of disturber and test cables that may be in different arrangements and/or configurations relative to one another.

Reference is now made to FIG. 3, which is a block diagram of a method for demonstrating cabling performance in real time according to some embodiments of the present invention. Multiple disturber cables are arranged proximate a test cable (block 130). As discussed above regarding FIG. 2, the test cable may be surrounded by multiple disturber cables. The test cable and at least one of the disturber cables are each terminated between two data transceivers (block 132). The data transceivers may be used to transmit signals via at least one of the disturber cables (block 134). In some embodiments, the signals transmitted via a disturber cable may be generated randomly. The data transceivers are also used to transmit data via the test cable (block 136). In some embodiments, the data transmitted via the test cable may include predetermined content and/or format. Using the data transmitted via the test cable, performance of the test cable is analyzed (block 138).

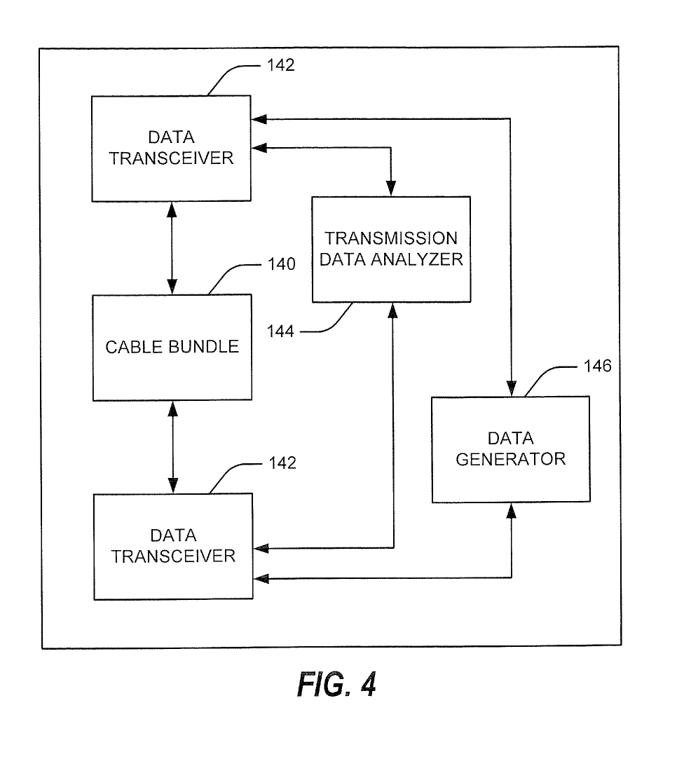

Reference is now made to FIG. 4, which is a block diagram of an apparatus for demonstrating cabling performance in real time according to some embodiments of the present invention. At least two data transceivers 142 are connected to ends of cables in a cable bundle 140. The cable bundle 140 may include a test cable and at least one disturber cable. A data generator 146 may generate data for transmission by the test cable and a disturber cable. In some embodiments, the data for the test cable is predetermined for ease of performance analysis. In some embodiments, the data for a disturber cable may be randomly generated and/or noise and/or control bits. Some embodiments provide that data for a disturber cable may include predetermined data content and/or format having known and/or predictable crosstalk characteristics. A transmission data analyzer 144 analyzes data transmission performance of the test cable based on performance information generated by the data transceivers 142.

In some embodiments, a cabling demonstrator may include 10 GBASE-T evaluation boards and 100-meter UTP channels. In some embodiments, the evaluation boards and 100 meter UTP channels may be connected in a worst case, full reach, four-connector channel configuration (as specified in, for example, draft ISO/IEC 11801: 2002 Amendment including Class E_{A}). The 10 GBASE-T signals may be launched through a generator at an interface to the evaluation boards. The signals from the receive packets, or frames, at the far end transceiver may be compared to those from the send frames. In some embodiments, full capacity traffic may be carried simultaneously on all disturbing channels, simulating a worst-case environment for alien crosstalk. In some embodiments, the evaluation boards may be linked peer-to-peer through the cabling to form multiple channels over UTP cabling. In some embodiments, fourteen evaluation boards may be used in total to form seven 10 GBASE-T channels over UTP cabling. Some embodiments provide that load modules are used for assessing the raw bandwidth of the channel and a client/server architecture may be used for benchmarking network throughput.

Some embodiments provide that the cabling channel configurations may include a “six-around-one” configuration with six disturbing cables tightly bundled around one “test” or “disturbed” cable, however, the embodiments are not so limited. All cross-connect cords and horizontal cables may be structurally bundled. On the test channel, two load modules may continually transmit and receive 10 GBASE-T Ethernet Data frames in full duplex. On one disturber channel, the server may continuously transmit 10 GBASE-T Ethernet data frames to the client by running any of a variety of a file streaming and/or network benchmarking software programs. The remaining 5 disturber channels may be continuously energized with 10 GBASE-T control signals. Although these five channels don't have active 10 G Ethernet payload data, the control signals may be scrambled through a scrambler polynomial, and the signals transmitted onto the media generate representative alien crosstalk comparable to adjacent 10 GBASE-T channels.

Load modules may be connected peer-to-peer, which may represent the application scenario of a switch-to-switch 10 GBASE-T backbone channel over UTP cabling. In some embodiments, software may be used to display the data in graphical and/or tabular form. In some embodiments, the server and client may include personal computers and/or workstations that may include network interface cards (NIC). Although server and client machines may be distinguished by names, the client/server architecture may be symmetric. For example, the server can work as a client, and vice versa. In some embodiments, a network benchmarking software program may be configured to continually transfer data files to the client. In some embodiments, the measurement unit of system CPU load may be expressed as a percentage.

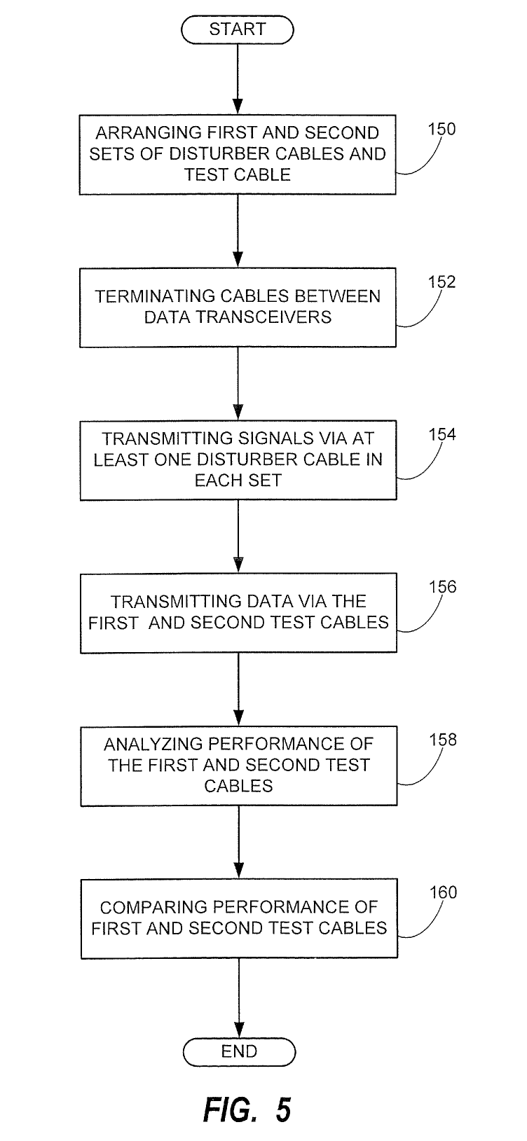

Reference is now made to FIG. 5, which is a block diagram illustrating a method for demonstrating cabling performance in real time according to some embodiments of the present invention. First and second sets of disturber cables are arranged and configured to generate externally originating noise proximate respective first and second test cables within the first and second disturber cable sets (block 150). For example, a first cable bundle may include first disturber cables and a first test cable and a second cable bundle may include second disturber cables and a second test cable.

Each end of the cables are terminated between data transceivers (block 152). For example, some embodiments provide that each cable (disturber and test) is terminated between two of the data transceivers. Some embodiments provide that the first and second cable bundles may be tested simultaneously while other embodiments provide that the first and second cable bundles may be tested individually and the results of each test stored and/or compared.

Random signals may be transmitted at least one of the first set of disturber cables and at least one of the second set disturber cables (block 154). Some embodiments provide that multiple combinations of disturber cables may be used to transmit the random signals to simulate multiple different cross-talk circumstances.

Test data is transmitted via the first test cable and via the second test cable (block 156) and the respective performances of the first test cable and the second test cable are analyzed (block 158). Some embodiments provide that analyzing the performance of the first test cable and the second test cable includes determining a real-time signal-to-noise ratio (“SNR”) for each of the first and second test cables. In some embodiments, analyzing the performance of the first test cable and the second test cable includes determining the real-time SNR on each of multiple differential conductor pairs included within the each of the first test cable and the second test cable. The performances of the first and second test cables are compared (block 160).

In the drawings and specification, there have been disclosed typical embodiments of the invention and, although specific terms are employed, they are used in a generic and descriptive sense only and not for purposes of limitation, the scope of the invention being set forth in the following claims. Moreover, those skilled in the art will readily appreciate that many modifications are possible to the exemplary embodiments that are described in detail in the present specification that do not materially depart from the novel teachings and advantages of this invention. Accordingly, all such modifications are intended to be included within the scope of this invention as defined in the claims and equivalents thereof.

That which is claimed is:

1. An apparatus for demonstrating cable performance in real time, the apparatus comprising:
a cable bundle of a plurality of disturber cables and a test cable arranged proximate one another;
a plurality of data transceivers that are connected in pairs across the test cable and across at least one of the plurality of disturber cables;
a data generator that is configured to generate data for transmission across the at least one of the plurality of disturber cables and the test cable; and
a transmission data analyzer that is configured to analyze data transmission performance of the test cable.

2. The apparatus according to claim 1, wherein data transmission performance includes a real-time signal-to-noise ratio (“SNR”).

3. The apparatus according to claim 2, wherein the transmission data analyzer determines the real time SNR on the test cable.

4. The apparatus according to claim 2, wherein the transmission data analyzer determines the real time SNR on each of a plurality of differential conductor pairs included within the test cable.

5. The apparatus according to claim 2, further comprising a visual output device that is configured to display the real-time SNR as an average SNR and a worst value SNR.

6. The apparatus according to claim 2,
wherein the data for transmission across the at least one of the plurality of disturber cables comprises a combination of noise sources, and
wherein the SNR includes a ratio of a received signal on the test cable divided by the combination of noise sources.

7. The apparatus according to claim 2, wherein the data for transmission across the at least one of the plurality of disturber cables is selectively stopped while the transmission data analyzer is analyzing the data transmission performance of the test cable to observe a change in the SNR and to determine a sensitivity to crosstalk corresponding to the at least one of the plurality of disturber cables.

8. The apparatus according to claim 2,
wherein the cable bundle comprises a first cable bundle and a second cable bundle,
wherein the first cable bundle includes a first test cable of a first type,
wherein the second cable bundle includes a second test cable of a second type that is different from the first type, and
wherein the transmission data analyzer is configured to analyze data transmission performance of the first test cable and the second test cable to provide comparative data transmission performance between the first and second test cables.

9. The apparatus according to claim 2, wherein the data generated for transmission across the at least one of the plurality of disturber cables includes randomly generated signals.

10. A method for demonstrating cable performance, comprising:
arranging a plurality of disturber cables that are configured to generate externally originating noise proximate a test cable that is configured to be analyzed for performance;
terminating each end of at least one of the plurality of disturber cables and the test cable between respective a plurality of data transceivers, wherein each cable is terminated between two of the plurality of data transceivers;
transmitting random signals via the at least one of the plurality of disturber cables;
transmitting data via the test cable; and
analyzing the performance of the test cable.

11. The method according to claim 10, wherein analyzing the performance of the test cable comprises determining a real-time signal-to-noise ratio (“SNR”).

12. The method according to claim 11, wherein determining the real-time SNR comprises determining the real-time SNR on the test cable.

13. The method according to claim 11, wherein determining the real-time SNR comprises determining the real-time SNR on each of a plurality of differential conductor pairs included within the test cable.

14. The method according to claim 11, wherein determining the real-time SNR on the test cable comprises determining an average SNR and a worst value of SNR on the test cable.

15. The method according to claim 11, further comprising displaying the SNR using a visual output device and storing the SNR on a computer readable medium.

16. The method according to claim 11, wherein transmitting random signals via the at least one of the plurality of disturber cables comprises selectively stopping transmitting random signals via the at least one of the plurality of disturber cables while analyzing the performance of the test cable and determining a change in the performance of the test cable to determine a sensitivity to crosstalk corresponding to the at least one of the plurality of disturber cables.

17. The method according to claim 11,
wherein the random signals transmitted across that least one of the plurality of disturber cables comprises a combination of noise sources, and
wherein the SNR includes a ratio of a received signal on the test cable divided by the combination of noise sources.

18. A method for demonstrating cable performance, comprising:
arranging a first plurality of disturber cables and a second plurality of disturber cables that are configured to generate externally originating noise proximate respective first and second test cables that are each configured to be analyzed for performance;
terminating each end of at least one of the first plurality of disturber cables and at least one of the second plurality of disturber cables and the first and second test cables between respective ones of a plurality of data transceivers, wherein each cable is terminated between two of the plurality of data transceivers;
transmitting random signals via the at least one of the first plurality of disturber cables and at least one of the second plurality of disturber cables;
transmitting data via the first test cable and via the second test cable;
analyzing the performance of the first test cable and the second test cable; and
comparing the performance of the first test cable and the second test cable.

19. The method according to claim 18, wherein analyzing the performance of the first test cable and the second test cable comprises determining a real-time signal-to-noise ratio (“SNR”) for each of the first and second test cables.

20. The method according to claim 18, wherein analyzing the performance of the first test cable and the second test cable comprises determining the real-time SNR on each of a plurality of differential conductor pairs included within the each of the first test cable and the second test cable.
